(19) United States
(12) Patent Application Publication
(10) Pub. No.: US 2024/0260372 A1
(43) Pub. Date: Aug. 1, 2024

(54) DISPLAY DEVICE AND ELECTRONIC APPARATUS

(71) Applicant: SEIKO EPSON CORPORATION, Tokyo (JP)

(72) Inventor: Hitoshi Ota, Shiojiri-shi (JP)

(73) Assignee: SEIKO EPSON CORPORATION, Tokyo (JP)

(21) Appl. No.: 18/427,013

(22) Filed: Jan. 30, 2024

(30) Foreign Application Priority Data
Jan. 31, 2023 (JP) 2023-012631

(51) Int. Cl. H10K 59/35

(52) U.S. Cl. CPC H10K 59/353

(57) ABSTRACT

In each of a plurality of pixels, a first sub-pixel, a second sub-pixel, and a third sub-pixel are adjacent to each other, a first light-emitting region overlaps a second when viewed in a first direction, a third light-emitting region overlaps the first and second regions when viewed in a second direction orthogonal to the first, the first light-emitting region has a shape including a first notch on a side opposite to the second light-emitting region which has a shape including a second notch on a side opposite to the first in plan view from a third direction orthogonal to the first and second directions, at least one of a first contact hole and a third contact hole of an adjacent pixel of the plurality of pixels is provided in a region of the first notch, and a second contact hole is provided in a region of the second notch.

The present application is based on, and claims priority from JP Application Serial Number 2023-012631, filed Jan. 31, 2023, the disclosure of which is hereby incorporated by reference herein in its entirety.

### BACKGROUND

### 1. Technical Field

The present disclosure relates to a display device and an electronic apparatus.

### 2. Related Art

Display devices including a light-emitting element such as an organic electroluminescence (EL) element are known.

For example, JP-A-2016-45304 discloses a display device in which a light-emitting portion is formed in an L-shape and a contact hole for electrically coupling a pixel electrode and a pixel circuit is formed in a region where the light-emitting portion is not formed.

In the display device described above, it is desired to improve image quality.

### SUMMARY

A display device according to an aspect of the present disclosure is a display device including a plurality of pixels, in which each of the plurality of pixels includes a first sub-pixel including a first light-emitting region, a first pixel electrode, and a first pixel circuit configured to control light emission in the first light-emitting region, the first sub-pixel being configured to emit first color light, a second sub-pixel including a second light-emitting region, a second pixel electrode, and a second pixel circuit configured to control light emission in the second light-emitting region, the second sub-pixel being configured to emit second color light different from the first color light, and a third sub-pixel including a third light-emitting region, a third pixel electrode, and a third pixel circuit configured to control light emission in the third light-emitting region, the third sub-pixel being configured to emit third color light different from the first color light and the second color light, and in each of the plurality of pixels, the first sub-pixel, the second sub-pixel, and the third sub-pixel are adjacent to each other, the first light-emitting region overlaps the second light-emitting region when viewed in a first direction, the third light-emitting region overlaps the first light-emitting region and the second light-emitting region when viewed in a second direction orthogonal to the first direction, the first light-emitting region has a shape including a first notch on a side opposite to the second light-emitting region in a plan view from a third direction orthogonal to the first direction and the second direction, the second light-emitting region has a shape including a second notch on a side opposite to the first light-emitting region, the first pixel electrode and the first pixel circuit are electrically coupled to each other via a first contact hole formed in an insulating layer provided between the first pixel electrode and the first pixel circuit, the second pixel electrode and the second pixel circuit are electrically coupled to each other via a second contact hole formed in an insulating layer provided between the second pixel electrode and the second pixel circuit, the third pixel electrode and the third pixel circuit are electrically coupled to each other via a third contact hole formed in an insulating layer provided between the third pixel electrode and the third pixel circuit, at least one of the first contact hole and the third contact hole of an adjacent pixel of the plurality of pixels is provided in a region of the first notch, and the second contact hole is provided in a region of the second notch.

An electronic apparatus according to an aspect of the present disclosure includes the display device according to an aspect.

### BRIEF DESCRIPTION OF THE DRAWINGS

FIG. 1 is a perspective view schematically illustrating a display device according to this embodiment.

FIG. 2 is a plan view schematically illustrating a display panel of the display device according to this embodiment.

FIG. 3 is a circuit diagram illustrating a pixel circuit of a sub-pixel of the display device according to this embodiment.

FIG. 4 is a cross-sectional view schematically illustrating a pixel of the display device according to this embodiment.

FIG. 5 is a plan view schematically illustrating a pixel of the display device according to this embodiment.

FIG. 6 is a diagram illustrating a color change depending on a viewing angle.

FIG. 7 is a plan view schematically illustrating a pixel of a display device according to a first modification example of this embodiment.

FIG. 8 is a plan view schematically illustrating a pixel of a display device according to a second modification example of this embodiment.

FIG. 9 is a perspective view schematically illustrating a head-mounted display according to this embodiment.

FIG. 10 is a diagram schematically illustrating an image forming device and a light-guiding device of the head-mounted display according to this embodiment.

### DESCRIPTION OF EMBODIMENTS

Preferred embodiments of the present disclosure will be described in detail below with reference to the drawings. Note that the embodiments described below do not unduly limit the content of the present disclosure described in the claims. In addition, not all the configurations described below are essential constituent elements of the present disclosure.

### 1. Display Device

### 1.1. Overall Configuration

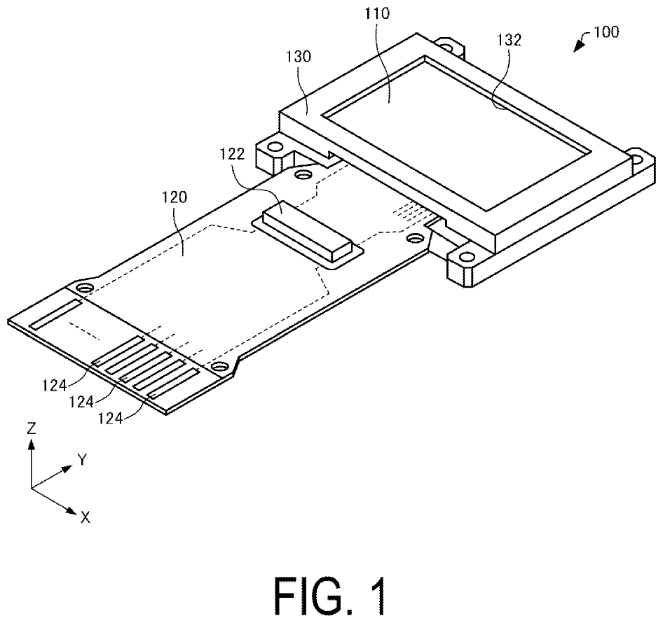

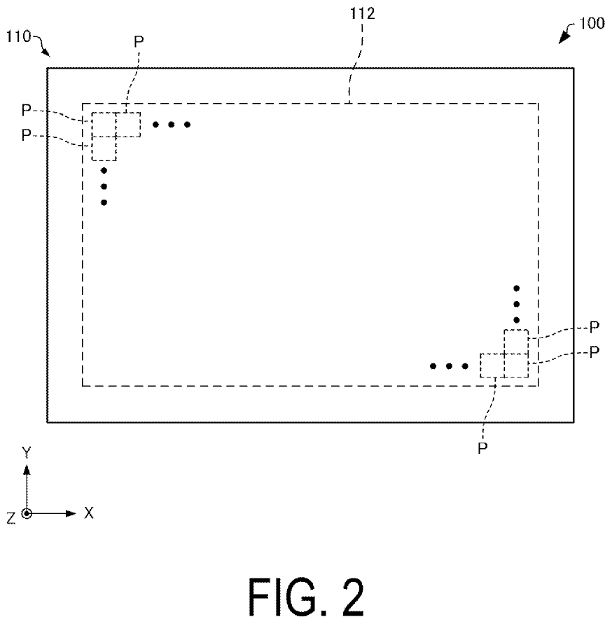

First, a display device according to this embodiment will be described with reference to the drawings. FIG. 1 is a perspective view schematically illustrating a display device 100 according to this embodiment. FIG. 2 is a plan view schematically illustrating a display panel 110 of the display device 100 according to this embodiment. Note that FIGS. 1 and 2 illustrate an X-axis, a Y-axis, and a Z-axis as three axes orthogonal to each other.

For example, as illustrated in FIG. 1, the display device 100 includes the display panel 110, a flexible printed circuit (FPC) 120, and a frame body 130 that fixes the display panel 110.

The FPC 120 is electrically coupled to the display panel 110. A driver integrated circuit (IC) 122 for driving the display panel 110 is mounted on the FPC 120. The FPC 120 includes a plurality of external coupling terminals 124. The external coupling terminals 124 are terminals for inputting an input signal such as image information from an external circuit to the driver IC 122. The frame body 130 is provided with a window frame 132 through which display on the display panel 110 can be visually recognized.

As illustrated in FIG. 2, the display panel 110 includes a display region 112. In the example illustrated in the drawing, the display region 112 is a rectangle with long sides parallel to the X-axis. In the display panel 110, a plurality of pixels P as display units are disposed in a matrix at a predetermined arrangement pitch. In the example illustrated in the drawing, the plurality of pixels P are arrayed in a matrix in the X direction and the Y direction. Although not illustrated in FIG. 2, the pixels P include, for example, red sub-pixels capable of displaying red, green sub-pixels capable of displaying green, and blue sub-pixels capable of displaying blue. Note that in FIG. 2, the pixel P is illustrated in a simplified manner.

### 1.2. Electrical Configuration of Sub-Pixel

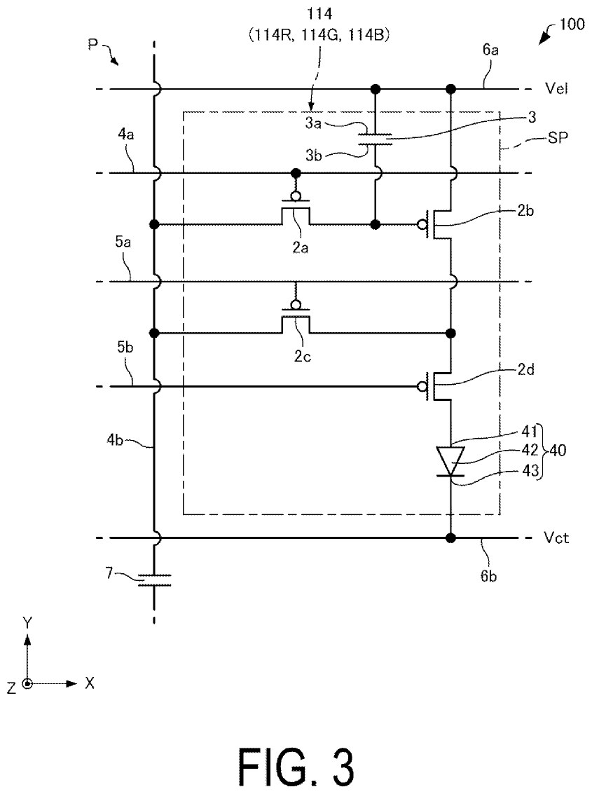

FIG. 3 is a circuit diagram illustrating a pixel circuit 114 of a sub-pixel SP of the pixel P. The red sub-pixel capable of displaying red includes a first pixel circuit 114R as the pixel circuit 114. The green sub-pixel capable of displaying green includes a second pixel circuit 114G as the pixel circuit 114. The blue sub-pixel capable of displaying blue includes a third pixel circuit 114B as the pixel circuit 114.

As illustrated in FIG. 3, the pixel circuit 114 of the sub-pixel SP includes, for example, four transistors 2a, 2b, 2c, and 2d, a storage capacitor 3, and an organic EL element 40. In the display region 112 of the display panel 110, a scanning line 4a, a data line 4b, a first control line 5a, a second control line 5b, a first power supply wiring line 6a, and a second power supply wiring line 6b are provided.

The pixel circuit 114 is provided between the first power supply wiring line 6a and the second power supply wiring line 6b. The scanning line 4a, the first control line 5a, and the second control line 5b extend in the X-axis direction across the plurality of pixel circuits 114 arranged in the X-axis direction. The data line 4b extends in the Y-axis direction across the plurality of pixel circuits 114 arranged in the Y-axis direction. The capacitive element 7 is coupled to an input side of the data line 4b in series.

The pixel circuit 114 includes, for example, a writing control transistor 2a, a drive transistor 2b, a compensation transistor 2c, and a light emission control transistor 2d. The transistors 2a, 2b, 2c, and 2d may be of a P-channel type or an N-channel type.

The organic EL element 40 includes a pixel electrode 41 as an anode, a common electrode 43 as a cathode, and a light-emitting functional layer 42 provided between the pixel electrode 41 and the common electrode 43. The pixel electrode 41 is an electrode provided for each of the plurality of sub-pixels SP. The common electrode 43 is an electrode provided in common across the plurality of sub-pixels SP.

The light-emitting functional layer 42 of the organic EL element 40 includes a light-emitting layer containing an organic light-emitting material. The light-emitting functional layer 42 emits, for example, white light.

The organic EL element 40 is coupled between the first power supply wiring line 6a and the second power supply wiring line 6b via the drive transistor 2b and the light emission control transistor 2d. A high power supply potential Vel is supplied to the first power supply wiring line 6a. A low power supply potential Vct is supplied to the second power supply wiring line 6b. The power supply potential Vct is, for example, a ground potential.

A source of the drive transistor 2b is coupled to, for example, the first power supply wiring line 6a. A drain of the drive transistor 2b is coupled to, for example, a source of the light emission control transistor 2d. A drain of the light emission control transistor 2d is coupled to the pixel electrode 41 of the organic EL element 40. The common electrode 43 of the organic EL elements 40 is coupled to the second power supply wiring line 6b.

A gate of the writing control transistor 2a is coupled to the scanning line 4a. A source of the writing control transistor 2a is coupled to, for example, the data line 4b. A drain of the writing control transistor 2a is coupled to, for example, a gate of the drive transistor 2b. One capacitor electrode 3a of the storage capacitor 3 is coupled to the first power supply wiring line 6a. The other capacitor electrode 3b of the storage capacitor 3 is coupled to the drain of the writing control transistor 2a.

A gate of the compensation transistor 2c is coupled to the first control line 5a. A source of the compensation transistor 2c is coupled to, for example, the data line 4b. A drain of the compensation transistor 2c is coupled to, for example, the source of the light emission control transistor 2d. The second control line 5b is coupled to the gate of the light emission control transistor 2d.

Note that in the source-drain coupling of the transistors 2a, 2b, 2c, and 2d, the source and the drain may be reversed. For example, the drain of the writing control transistor 2a may be coupled to the data line 4b, and the source of the writing control transistor 2a may be coupled to the gate of the drive transistor 2b.

The scanning line 4a is coupled to a scanning line drive circuit that supplies a scanning signal. The data line 4b is coupled to one end of the capacitive element 7. The other end of the capacitive element 7 is coupled to a data line drive circuit that supplies a data signal based on an image signal. The data signal is supplied to the capacitive element 7, and a potential corresponding to the data signal is supplied to the data line 4b.

The display device 100 includes a compensation period and a writing period in a horizontal scanning period. The scanning line drive circuit sequentially selects each of the plurality of scanning lines 4a for each horizontal scanning period by supplying a scanning signal to the scanning line 4a. The writing control transistor 2a of the pixel circuit 114 corresponding to the scanning line 4a selected by the scanning line drive circuit transitions to an ON state. Further, the drive transistor 2b of the pixel circuit 114 also transitions to an ON state.

The scanning line drive circuit sequentially selects each of the plurality of first control lines 5a for each compensation period by supplying a control signal to the first control line 5a. The compensation transistor 2c of the pixel circuit 114 corresponding to the first control line 5a selected by the scanning line drive circuit transitions to an ON state. Then, the storage capacitor 3 stores a threshold voltage |Vth| of the drive transistor 2c until the end of the compensation period in which the compensation transistor 2b is set to be in an OFF state.

When the compensation transistor 2c of the pixel circuit 114 is controlled to be in an OFF state by the scanning line drive circuit supplying a control signal to the first control line 5a, a path from the data line 4b to a gate electrode of the drive transistor 2b is in a floating state. On the other hand, a gate potential of the drive transistor 2b is maintained at a potential of (Vel−|Vth|) by the storage capacitor 3.

Next, the data line drive circuit supplies a gradation potential (data signal) corresponding to a gradation designated for each pixel circuit 114 by an image signal supplied from an external circuit to the capacitive element 7 in parallel for each writing period. Then, the level of the gradation potential is shifted using the capacitive element 7, and the potential is supplied to the gate of the drive transistor 2b of the pixel circuit 114 via the data line 4b and the writing control transistor 2a. The storage capacitor 3 stores a voltage corresponding to the gradation potential while compensating for the threshold voltage |Vth| of the drive transistor 2b.

On the other hand, when the selection of the scanning line 4a in the writing period is terminated, the scanning line drive circuit supplies a control signal to the second control line 5b to perform control so that the light emission control transistor 2d of the pixel circuit 114 corresponding to the second control line 5b is set to be in an ON state. Thereby, a driving current corresponding to the voltage stored in the storage capacitor 3 in the preceding writing period is supplied from the drive transistor 2b to the organic EL element 40 via the light emission control transistor 2d. The organic EL element 40 emits light with a brightness corresponding to the amount of driving current.

As described above, the organic EL element 40 emits light with a brightness corresponding to the gradation potential, and thus any image designated by the image signal is displayed. In the driving current supplied from the drive transistor 2b to the organic EL element 40, the influence of the threshold voltage is canceled. For this reason, even when the threshold voltage of the drive transistor 2b varies for each pixel circuit 114, the variation is compensated for. In addition, since the driving current corresponding to the gradation level is supplied to the organic EL element 40, it is possible to suppress the occurrence of display unevenness that impairs the uniformity of a display screen. As a result, it is possible to achieve high-quality display.

Note that the pixel circuit 114 is not limited to the configuration including the four transistors 2a, 2b, 2c, and 2d. The pixel circuit 114 may be configured not to include the compensation transistor 2c as long as, for example, a variation in the threshold voltage of the drive transistor 2b for each pixel circuit 114 is small.

In addition, a configuration of a signal wiring line is not particularly limited. For example, although the scanning line 4a and the first control line 5a are different wiring lines in the above description, the scanning line 4a and the first control line 5a may be one wiring line.

### 1.3. Cross-Sectional Structure of Pixel

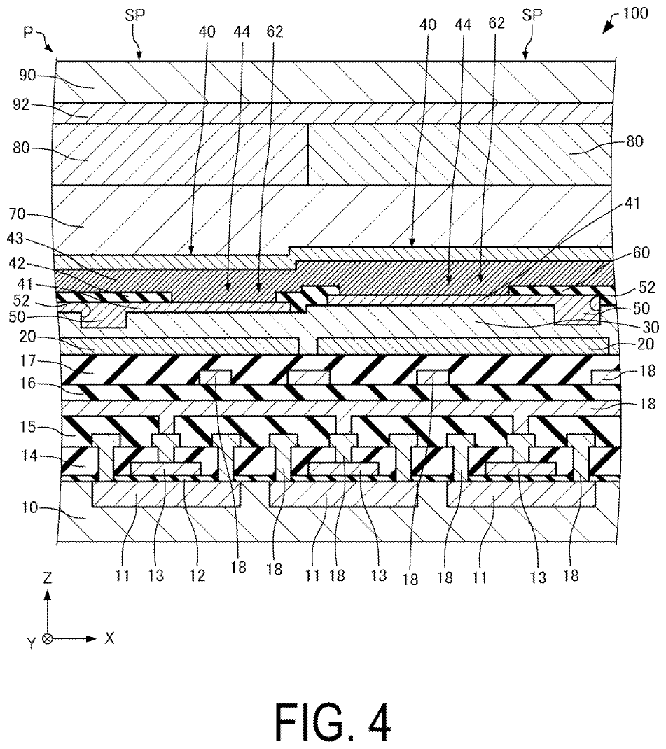

FIG. 4 is a diagram schematically illustrating the pixel P of the display device 100.

As illustrated in FIG. 4, the pixel P includes, for example, a substrate 10, interlayer insulating layers 14, 15, 16, and 17, a wiring line layer 18, a reflective layer 20, an insulating layer 30, an organic EL element 40, a contact 50, an insulating layer 60, a sealing layer 70, a colored layer 80, and a counter substrate 90.

The substrate 10 is, for example, a silicon substrate. The substrate 10 is provided with impurity regions 11 into which impurities are ion-implanted. The impurity regions 11 function as sources or drains of the transistors 2a, 2b, 2c, and 2d described above. A gate insulating layer 12 is provided on the substrate 10. The material of the gate insulating layer 12 is, for example, oxide silicon. A gate electrode 13 is provided on the gate insulating layer 12. The material of the gate electrode 13 is, for example, a metal, polysilicon, or the like. The substrate 10, the impurity region 11, the gate insulating layer 12, and the gate electrode 13 constitute the transistors 2a, 2b, 2c, and 2d described above. The substrate 10, the impurity region 11, the gate insulating layer 12, and the gate electrode 13 constitute the pixel circuit 114 described above.

The interlayer insulating layer 14 covers the gate insulating layer 12 and the gate electrode 13. The interlayer insulating layers 14, 15, 16, and 17 are layered in that order from the substrate 10 side. The interlayer insulating layers 14, 15, 16, and 17 are, for example, silicon oxide layers.

The wiring line layer 18 is provided on the interlayer insulating layer 14, the interlayer insulating layer 15, and the interlayer insulating layer 16. The material of the wiring line layer 18 is, for example, a metal such as aluminum or copper. The wiring line layer 18 constitutes the scanning line 4a, the data line 4b, the control lines 5a and 5b, and the power supply wiring lines 6a and 6b described above.

The reflective layer 20 is provided on the interlayer insulating layer 17. The reflective layer 20 is provided between the interlayer insulating layer 17 and the insulating layer 30. The reflective layer 20 is provided for each of the plurality of sub-pixels SP. Two sub-pixels SP are illustrated in FIG. 2. The material of the reflective layer 20 is, for example, a metal such as aluminum. The reflective layer 20 reflects light toward the colored layer 80, the light being generated by the organic EL element 40 and traveling toward the substrate 10.

The insulating layer 30 is provided on the reflective layer 20. The insulating layer 30 is provided between the reflective layer 20 and the organic EL element 40. The insulating layer 30 is provided between the pixel circuit 114 and the pixel electrode 41. The insulating layer 30 has different thicknesses in the sub-pixel SP that emits red light, the green sub-pixel SP that emits green light, and the blue sub-pixel SP that emits blue light. The insulating layer 30 has, for example, a layered structure in which a plurality of layers are layered. The insulating layer 30 includes different numbers of layered layers in the sub-pixel SP that emits red light, the green sub-pixel SP that emits green light, and the blue sub-pixel SP that emits blue light. The insulating layer 30 is, for example, a silicon oxide layer, a silicon nitride layer, a silicon oxynitride layer, or the like.

The organic EL element 40 is provided on the insulating layer 30. The organic EL element 40 is provided between the insulating layer 30 and the sealing layer 70. The organic EL element 40 is, for example, an organic light-emitting diode (OLED). The organic EL element 40 includes a pixel electrode 41, a light-emitting functional layer 42, and a common electrode 43.

The pixel electrode 41 is provided on the insulating layer 30. The pixel electrode 41 is provided between the insulating layer 30 and the light-emitting functional layer 42. The pixel electrode 41 is provided for each of the plurality of sub-pixels SP. The pixel electrode 41 transmits light generated in the light-emitting functional layer 42. The pixel electrode 41 is a transparent electrode made of, for example, indium tin oxide (ITO). The pixel electrode 41 is one electrode for injecting a current into the light-emitting functional layer 42.

The light-emitting functional layer 42 is provided on the pixel electrode 41. The light-emitting functional layer 42 is provided between the pixel electrode 41 and the common electrode 43. The light-emitting functional layer 42 is continuously provided in the plurality of sub-pixels SP. The light-emitting functional layer 42 is configured, for example, by layering a plurality of light-emitting layers. The light-emitting functional layer 42 emits, for example, white light.

The common electrode 43 is provided on the light-emitting functional layer 42. The common electrode 43 is provided between the light-emitting functional layer 42 and the sealing layer 70. The common electrode 43 is a common electrode that is continuously provided in the plurality of sub-pixels SP. The material of the common electrode 43 is, for example, an alloy of magnesium and silver. The common electrode 43 is the other electrode for injecting a current into the light-emitting functional layer 42.

The common electrode 43, the insulating layer 30, and the reflective layer 20 form an optical resonance structure. The thickness of the insulating layer 30 is adjusted to form a standing wave having a predetermined wavelength between the reflective layer 20 and the common electrode 43. Thereby, light having a predetermined wavelength can be emitted from the organic EL element 40 for each of the plurality of sub-pixels SP.

The contact 50 is coupled to the pixel electrode 41. The contact 50 is provided in a contact hole 52 formed in the insulating layer 30. The contact 50 is provided between the reflective layer 20 and the pixel electrode 41. A plurality of contacts 50 are provided corresponding to the plurality of pixel electrodes 41. The contact 50 is provided integrally with the pixel electrode 41, for example. The contact 50 is electrically coupled to the wiring line layer 18. A current flowing through the wiring line layer 18 is supplied to the pixel electrode 41 via the contact 50. In this embodiment, the contact 50 is provided integrally with the pixel electrode 41, but the present disclosure is not limited thereto. The contact 50 and the pixel electrode 41 may be made of different materials.

The insulating layer 60 covers the contact 50. The insulating layer 60 overlaps the contact 50 when viewed in the Z-axis direction (hereinafter also referred to as “in plan view”). The insulating layer 60 is provided on the pixel electrode 41. The insulating layer 60 is provided between the pixel electrode 41 and the light-emitting functional layer 42. The insulating layer 60 overlaps the outer edge of the pixel electrode 41 in plan view. The insulating layer 60 is, for example, a silicon oxide layer, a silicon nitride layer, or a silicon oxynitride layer.

An opening 62 is formed in the insulating layer 60. An opening 62 extends through the insulating layer 60. The insulating layer 60 defines a light-emitting region 44 of the organic EL element 40. The light-emitting region 44 is a region overlapping the opening 62 of the organic EL element 40 in plan view. In other words, the light-emitting region 44 is a region where the pixel electrode 41 and the light-emitting functional layer 42 are in contact with each other in plan view. The light-emitting region 44 does not overlap the insulating layer 60 in plan view. In the region where the insulating layer 60 is provided, supply of holes from the pixel electrode 41 to the light-emitting functional layer 42 is suppressed, and light emission from the light-emitting functional layer 42 is suppressed. In the organic EL element 40, the region overlapping the contact 50 is not used as the light-emitting region 44, and thus it is possible to suppress blockage of light by the contact 50. The pixel circuit 114 controls light emission of the light-emitting functional layer 42 in the light-emitting region 44.

The sealing layer 70 is provided on the common electrode 43. The sealing layer 70 is provided between the common electrode 43 and the colored layer 80. The sealing layer 70 is continuous in the plurality of sub-pixels SP. The sealing layer 70 is configured, for example, by layering an inorganic layer and an organic layer. The sealing layer 70 may have a structure in which an organic layer is sandwiched between a pair of inorganic layers. The inorganic layer is, for example, a silicon oxide layer, a silicon nitride layer, or a silicon oxynitride layer. The inorganic layer protects the light-emitting functional layer 42 from moisture, oxygen, and the like. The organic layer is, for example, an acrylic-based resin layer. The organic layer improves the flatness of the upper surface of the sealing layer 70.

The colored layer 80 is provided on the sealing layer 70. The colored layer 80 is provided between the sealing layer 70 and the counter substrate 90. The colored layer 80 is a color filter configured to transmit a predetermined wavelength in each of the sub-pixel SP that emits red light, the green sub-pixel SP that emits green light, and the blue sub-pixel SP that emits blue light. The material of the colored layer 80 is, for example, a color resist.

The counter substrate 90 is provided over the colored layer 80. In the example illustrated in the drawing, the counter substrate 90 is adhered to the colored layer 80 by an adhesive layer 92. The counter substrate 90 and the adhesive layer 92 transmit light emitted from the colored layer 80. The counter substrate 90 functions as a protective substrate that protects the organic EL element 40 and the colored layer 80.

Note that the pixel P of the display device 100 is manufactured using, for example, a known semiconductor manufacturing process.

### 1.4. Planar Structure of Pixel

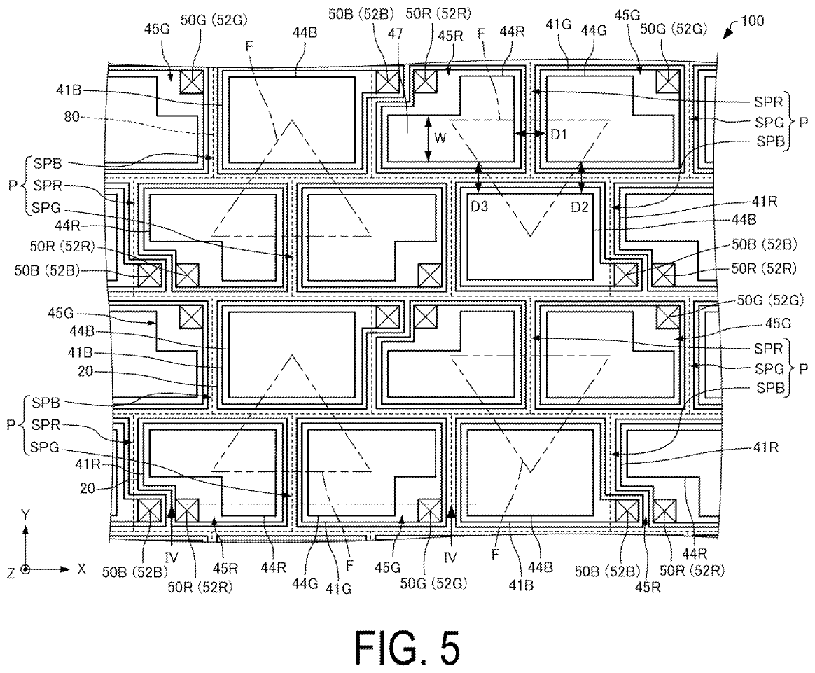

FIG. 5 is a plan view schematically illustrating the pixel P of the display device 100. FIG. 4 described above is a cross-sectional view taken along line IV-IV in FIG. 5. Note that for the sake of convenience, members other than the reflective layer 20, the pixel electrode 41, the light-emitting region 44, the contact 50, and the colored layer 80 are not illustrated in FIG. 5. The colored layer 80 is indicated by a dashed line.

As illustrated in FIG. 5, a plurality of pixels P are provided. The number of pixels P is not particularly limited as long as it is plural. The plurality of pixels P are arranged in a matrix in the X-axis direction and the Y-axis direction.

The shapes of the pixels P adjacent to each other in the X-axis direction have a complementary relationship in the Y-axis direction. That is, of the pixels P adjacent to each other in the X-axis direction, a shape obtained by inverting one pixel P in the Y-axis direction is a shape of the other pixel P. Thereby, since a color change becomes symmetrical in the Y-axis direction, it is possible to reduce the sense of incongruity of the color change depending on a viewing angle. On the other hand, the pixels P adjacent to each other in the Y-axis direction are disposed in the same shape.

The pixel P includes three sub-pixels SP. Specifically, the pixel P includes, as the three sub-pixels SP, a red sub-pixel SPR that emits red light, a green sub-pixel SPG that emits green light, and a blue sub-pixel SPB that emits blue light. The sub-pixels SPR, SPG, and SPB constituting one pixel P are adjacent to each other. In the plurality of pixels P, the sub-pixels SPR, SPG, and SPB are arranged in a delta arrangement. A figure F coupling the centers of the sub-pixels SPR, SPG, and SPB constituting one pixel P is, for example, a right triangle, an equilateral triangle, an isosceles triangle, or the like. In plan view, the outer edge of the colored layer 80 defines the shapes of the sub-pixels SPR, SPG, and SPB.

The red sub-pixel SPR includes a first pixel electrode 41R as the pixel electrode 41, a first pixel circuit 114R as the pixel circuit 114, a first light-emitting region 44R as the light-emitting region 44, and a first pixel contact 50R as the contact 50. The green sub-pixel SPG includes a second pixel electrode 41G as the pixel electrode 41, a second pixel circuit 114G as the pixel circuit 114, a second light-emitting region 44G as the light-emitting region 44, and a second pixel contact 50G as the contact 50. The blue sub-pixel SPB includes third pixel electrodes 41B as the pixel electrodes 41, third pixel circuits 114B as the pixel circuits 114, third light-emitting regions 44B as the light-emitting regions 44, and third pixel contacts 50B as the contacts 50. The first pixel electrode 41R is electrically coupled to the first pixel circuits 114R via a first contact hole 52R as the contact hole 52. The second pixel electrode 41G is electrically coupled to the second pixel circuit 114G via a second contact hole 52G as the contact hole 52. The third pixel electrode 41B is electrically coupled to the third pixel circuits 114B via a third contact hole 52B as the contact hole 52.

The first light-emitting region 44R, the second light-emitting region 44G, and the third light-emitting region 44B have a shape having a longitudinal direction in the X-axis direction. In the light-emitting regions 44R, 44G, and 44B, the size in the X-axis direction is larger than the size in the Y-axis direction. In the plurality of pixels P, the first light-emitting region 44R, the second light-emitting region 44G, and the third light-emitting region 44B are repeatedly provided side by side in the X-axis direction in this order.

The first light-emitting region 44R, the second light-emitting region 44G, and the third light-emitting region 44B are provided on the inner side of the outer edge of the pixel electrode 41 in plan view. The pixel electrode 41 is provided on the inner side of the outer edge of the reflective layer 20 in plan view. The reflective layer 20 is provided on the inner side of the colored layer 80 in plan view. In the example illustrated in the drawing, in the pixels P adjacent to each other in the X-axis direction, the reflective layer 20 of the red sub-pixel SPR and the reflective layer 20 of the blue sub-pixel SPB are separated from each other. The pixel electrode 41 and the colored layer 80 have, for example, a rectangular shape in plan view. Note that in the pixels P adjacent to each other in the X-axis direction, the respective reflective layers 20 may be continuous with each other.

In one pixel P, the first light-emitting region 44R overlaps the second light-emitting region 44G when viewed in the X-axis direction. In other words, when the first light-emitting region 44R is moved in the X-axis direction, the first light-emitting region 44R overlaps the second light-emitting region 44G. In one pixel P, the third light-emitting region 44B overlaps the first light-emitting region 44R and the second light-emitting region 44G when viewed in the Y-axis direction. In other words, when the third light-emitting region 44B is moved in the Y-axis direction, the third light-emitting region 44B overlaps the first light-emitting region 44R and the second light-emitting region 44G.

In one pixel P, the first light-emitting region 44R has a shape including a first notch 45R on a side opposite to the second light-emitting region 44G in plan view. The first notch 45R is provided on a side opposite to the second light-emitting region 44G. The first notch 45R is provided in the −X-axis direction side of the first light-emitting region 44R. The first light-emitting region 44R has a substantially L-shape due to the first notch 45R. When viewed in the Y-axis direction, the first notch 45R does not overlap the third light-emitting region 44B, for example.

The first pixel contact 50R (first contact hole 52R) is provided in the region of the first notch 45R. Further, a third pixel contact 50B (third contact hole 52B) is provided in the region of the first notch 45R. The third pixel contact 50B (third contact hole 52B) provided in the region of the first notch 45R is the third pixel contact 50B (third contact hole 52B) of the blue sub-pixel SPB of the pixel P adjacent to the pixel P including the first notch 45R in the X-axis direction. In the example illustrated in the drawing, in the region of the first notch 45R, the third pixel contact 50B (third contact hole 52B) is provided in the −X-axis direction of the first pixel contact 50R (first contact hole 52R).

The region of the first notch 45R has a shape having a longitudinal direction in the X-axis direction. In the region of the first notch 45R, the size in the X-axis direction is larger than the size in the Y-axis direction. In the example illustrated in the drawing, the first notch 45R has a rectangular shape.

In one pixel P, the second light-emitting region 44G has a shape including a second notch 45G on a side opposite to the first light-emitting region 44R in plan view. The second notch 45G is provided on a side opposite to the third light-emitting region 44B. The second notch 45G is provided in the +X-axis direction of the second light-emitting region 44G. The second light-emitting region 44G has a substantially L-shape due to the second notch 45G. When viewed in the Y-axis direction, the second notch 45G does not overlap the third light-emitting region 44B, for example. When viewed in the X-axis direction, the second notch 45G overlaps the first notch 45R.

A second pixel contact 50G (second contact hole 52G) is provided in the region of the second notch 45G. In the example illustrated in the drawing, the second notch 45G has a square shape.

The third light-emitting region 44B has, for example, a rectangular shape. The third light-emitting region 44B has a shape without a notch. The third pixel contact 50B (third contact hole 52B) for causing the third light-emitting region 44B to emit light is provided in the region of the first notch 45R of the pixel P adjacent to the pixel P including the third light-emitting region 44B. The area of the third light-emitting region 44B is larger than, for example, the area of the second light-emitting region 44G in plan view.

In one pixel P, a distance D1 between the first light-emitting region 44R and the second light-emitting region 44G, a distance D2 between the second light-emitting region 44G and the third light-emitting region 44B, and a distance D3 between the first light-emitting region 44R and the third light-emitting region 44B are, for example, equal to each other. The distance D1 is the shortest distance between the first light-emitting region 44R and the second light-emitting region 44G. The distance D2 is the shortest distance between the second light-emitting region 44G and the third light-emitting region 44B. The distance D3 is the shortest distance between the first light-emitting region 44R and the third light-emitting region 44B.

The maximum size of the first light-emitting region 44R in the X-axis direction, the maximum size of the second light-emitting region 44G in the X-axis direction, and the maximum size of the third light-emitting region 44B in the X-axis direction are, for example, equal to each other. The maximum size of the first light-emitting region 44R in the Y-axis direction, the maximum size of the second light-emitting region 44G in the Y-axis direction, and the maximum size of the third light-emitting region 44B in the Y-axis direction are, for example, equal to each other.

In one pixel P, the length of the side of the first light-emitting region 44R which faces the second light-emitting region 44G is the same as the length of the side of the second light-emitting region 44G which faces the first light-emitting region 44R. In the example illustrated in the drawing, the length of the side of the first light-emitting region 44R which is parallel to the Y-axis and in the +X-axis direction is the same as the length of the side of the second light-emitting region 44G which is parallel to the Y-axis and in the −X-axis direction.

### 1.5. Operational Effects

In the display device 100, in each of the plurality of pixels P, the red sub-pixel SPR as a first sub-pixel, the green sub-pixel SPG as a second sub-pixel, and the blue sub-pixel SPB as a third sub-pixel are adjacent to each other. The first light-emitting region 44R overlaps the second light-emitting region 44G when viewed in the X-axis direction as a first direction, and the third light-emitting region 44B overlaps the first light-emitting region 44R and the second light-emitting region 44G when viewed in the Y-axis direction as a second direction orthogonal to the first direction. In each of the plurality of pixels P, in plan view from the Z-axis direction as a third direction orthogonal to the first direction and the second direction, the first light-emitting region 44R has a shape including the first notch 45R on a side opposite to the second light-emitting region 44G, and the second light-emitting region 44G has a shape including the second notch 45G on a side opposite to the first light-emitting region 44R. The first pixel electrode 41R and the first pixel circuit 114R are electrically coupled to each other via the first contact hole 52R formed in the insulating layer 30 provided between the first pixel electrode 41R and the first pixel circuit 114R. The second pixel electrode 41G and the second pixel circuit 114G are electrically coupled to each other via the second contact hole 52G formed in the insulating layer 30 provided between the second pixel electrode 41G and the second pixel circuit 114G. The third pixel electrode 41B and the third pixel circuit 114B are electrically coupled to each other via the third contact hole 52B formed in the insulating layer 30 provided between the third pixel electrode 41B and the third pixel circuit 114B. At least one of the first contact hole 52R and the third contact hole 52B of the adjacent pixel P of the plurality of pixels P is provided in the region of the first notch 45R, and the second contact hole 52G is provided in the region of the second notch 45G.

For this reason, in the display device 100, color light beams emitted from the red sub-pixel SPR, the green sub-pixel SPG, and the blue sub-pixel SPB are easily mixed, as compared with a case where the first light-emitting region has a shape including a notch on the second light-emitting region side and the second light-emitting region has a shape including a notch on the first light-emitting region side. Thereby, image quality can be improved. In the display device 100, it is possible to bring the center of gravity of the first light-emitting region 44R, the center of gravity of the second light-emitting region 44G, and the center of gravity of the third light-emitting region 44B close to the center of the pixel P in plan view.

For example, when white light is emitted from a pixel by mixing color light beams emitted from a red sub-pixel, a green sub-pixel, and a blue sub-pixel, and when the first light-emitting region includes a notch on the second light-emitting region side or the second light-emitting region includes a notch on the first light-emitting region side, color light beams emitted from a red sub-pixel, a green sub-pixel, and a blue sub-pixel are less likely to be mixed, and the color purity of the white light decreases.

Furthermore, in the display device 100, at least one of the first contact hole 52R and the third contact hole 52B of the adjacent pixel P of the plurality of pixels P is provided in the region of the first notch 45R, and the second contact hole 52G is provided in the region of the second notch 45G, and thus the area of the pixel P can be reduced.

In the display device 100, the first contact hole 52R and the third contact hole 52B of the adjacent pixel P of the plurality of pixels P are provided in the region of the first notch 45R. For this reason, in the display device 100, it is not necessary to form the third light-emitting region 44B into a shape including a notch in order to provide the third contact hole 52B. Thereby, the area of the third light-emitting region 44B can be increased. Since the blue sub-pixel SPB including the third light-emitting region 44B emits blue light having a wavelength shorter than those of red light and green light, the blue sub-pixel SPB may deteriorate faster than the red sub-pixel SPR and the green sub-pixel SPG, and the brightness thereof is likely to decrease. For this reason, a decrease in the brightness of the blue sub-pixel SPB can be suppressed by increasing the area of the third light-emitting region 44B. Thereby, the brightness of the blue sub-pixel SPB can be brought close to the brightness of the sub-pixels SPR and SPG.

In the display device 100, the first light-emitting region 44R, the second light-emitting region 44G, and the third light-emitting region 44B have a shape having a longitudinal direction in the X-axis direction, and the first light-emitting region 44R, the second light-emitting region 44G, and the third light-emitting region 44B are arranged in the X-axis direction in the plurality of pixels P. For this reason, in the display device 100, it is possible to reduce a color change depending on a viewing angle.

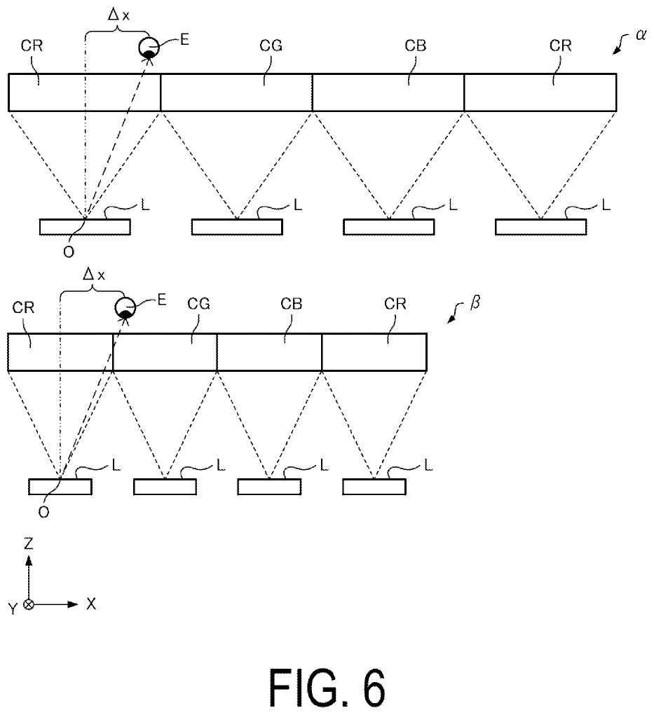

Here, FIG. 6 is a diagram illustrating a color change depending on a viewing angle. In FIG. 6, a plurality of light-emitting regions L are arranged in the X-axis direction. A red filter CR, a green filter CG, and a blue filter CB are arranged in the X-axis direction.

In the case of α illustrated in FIG. 6, light passing through the red filter CR is incident on an eye E located at a position Δ× away in the +X-axis direction from a center O of the light-emitting region L located closest to the −X-axis direction. For this reason, a color change is small when viewed from the position of the center O and when viewed from a position Δ× away from the center O in the +X-axis direction.

In the case of β illustrated in FIG. 6, the size of the light-emitting region L in the X-axis direction is smaller than that in the case of α. Accordingly, in the case of β, the sizes of the filters CR, CG, and CB in the X-axis direction are smaller than those in the case of α. In the case of β illustrated in FIG. 6, light passing through not only the red filter CR but also the green filter CG is incident on the eye E located at a position Δ× away from the center O in the +X-axis direction. For this reason, a color change is large when viewed from the position of the center O and when viewed from a position Δ× away from the center O in the +X-axis direction.

As described above, the larger the size of the light-emitting region L in the X-axis direction is, the smaller a color change depending on a viewing angle can be. In the display device 100, as described above, the light-emitting regions 44R, 44G, and 44B have a shape having a longitudinal direction in the X-axis direction, and in the plurality of pixels P, the light-emitting regions 44R, 44G, and 44B are arranged in the X-axis direction. Thus, it is possible to reduce a color change due to a viewing angle.

Furthermore, in the display device 100, the area ratios of the light-emitting regions 44R, 44G, and 44B can be adjusted by changing the sizes of the light-emitting regions 44R, 44G, and 44B in the X-axis direction.

In the display device 100, the region of the first notch 45R has a shape having a longitudinal direction in the X-axis direction. For this reason, for example, a width W of a narrow region 47 of the first light-emitting region 44R can be increased as compared with a case where the region of the first notch has a shape having a longitudinal direction in the Y-axis direction. In the example illustrated in the drawing, the narrow region 47 is located in the Y-axis direction of the first notch 45R. The width W is the size of the narrow region 47 in the Y-axis direction.

In the display device 100, in each of the plurality of pixels P, the distance D1 between the first light-emitting region 44R and the second light-emitting region 44G, the distance D2 between the second light-emitting region 44G and the third light-emitting region 44B, and the distance D3 between the first light-emitting region 44R and the third light-emitting region 44B are equal to each other. For this reason, in the display device 100, color light beams emitted from the light-emitting regions 44R, 44G, and 44B can be uniformly mixed.

### 2. Modification Examples of Display Device

### 2.1. First Modification Example

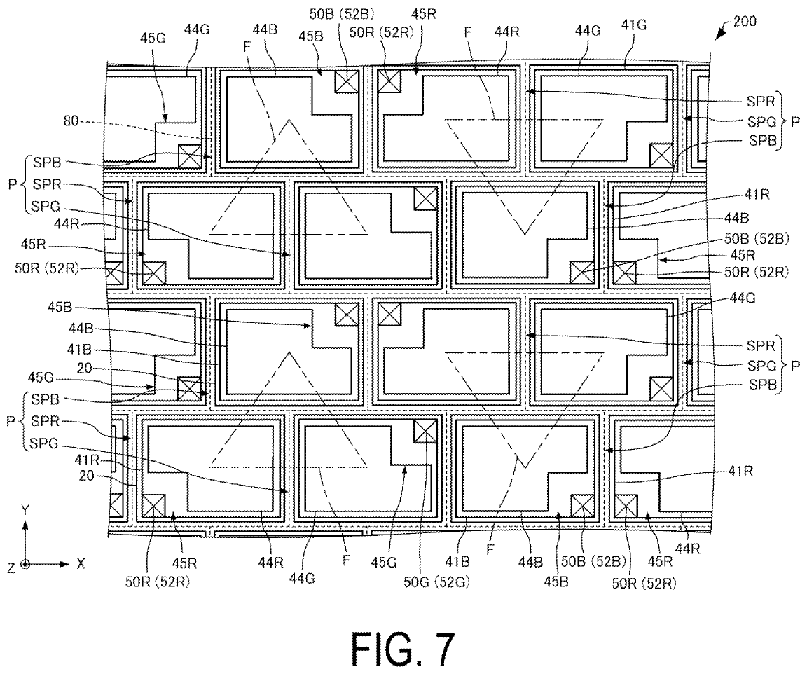

Next, a display device 200 according to a first modification example of this embodiment will be described with reference to the drawings. FIG. 7 is a plan view schematically illustrating a pixel P of the display device 200 according to the first modification example of this embodiment.

Hereinafter, in the display device 200 according to the first modification example of this embodiment, members having the same functions as the constituent members of the display device 100 according to this embodiment described above will be denoted by the same reference numerals, and detailed description thereof will be omitted. This also applies to a display device according to a second modification example of this embodiment, which will be described later.

In the display device 100 described above, as illustrated in FIG. 5, the third light-emitting region 44B has a rectangular shape.

On the other hand, in the display device 200, as illustrated in FIG. 7, in one pixel P, the third light-emitting region 44B has a shape including a third notch 45B on a side opposite to the second light-emitting region 44G in plan view.

The third light-emitting region 44B has a substantially L-shape due to the third notch 45B. In the example illustrated in the drawing, the notches 45R, 45G, and 45B have a square shape. The areas of the light-emitting regions 44R, 44G, and 44B are, for example, equal to each other.

In the region of the third notch 45B, the third pixel contact 50B (third contact hole 52B) of the blue sub-pixel SPB is provided. The third pixel contact 50B (third contact hole 52B) is not provided in the region of the first notch 45R. The first pixel contact 50R (first contact hole 52R) is provided in the region of the first notch 45R.

In the display device 200, in each of the plurality of pixels P, in plan view, the third light-emitting region 44B has a shape including the third notch 45B on a side opposite to the second light-emitting region 44G, the first pixel contact 50R (first contact hole 52R) of the red sub-pixel SPR is provided in the region of the first notch 45R, and the third pixel contact 50B (third contact hole 52B) of the blue sub-pixel SPB is provided in the region of the third notch 45B. For this reason, in the display device 200, it is possible to reduce a difference between the area of the first light-emitting region 44R, the area of the second light-emitting region 44G, and the area of the third light-emitting region 44B. Thereby, when a difference in a deterioration rate between the sub-pixels SPR, SPG, and SPB is small, a difference in brightness between the sub-pixels SPR, SPG, and SPB can be reduced.

### 2.2. Second Modification Example

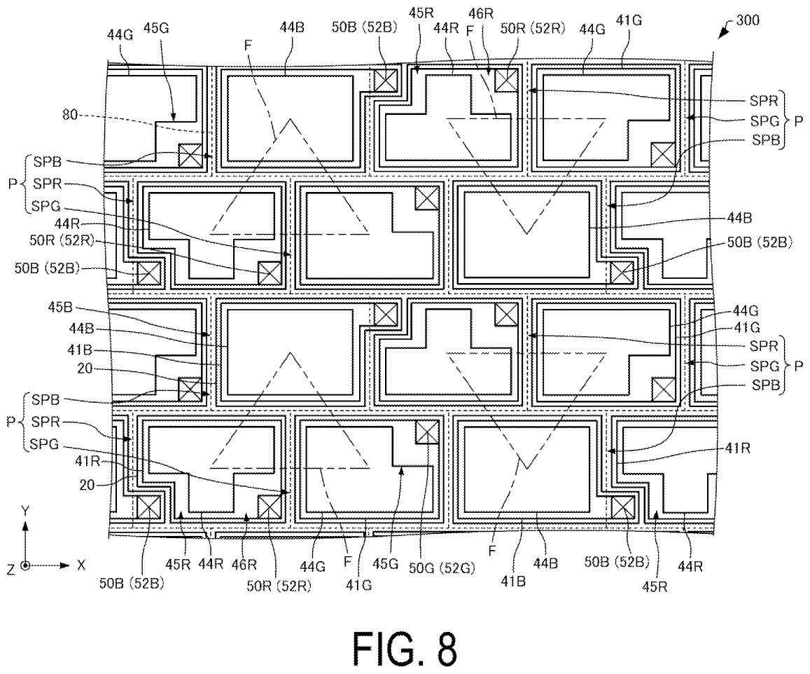

Next, a display device 300 according to a second modification example of this embodiment will be described with reference to the drawings. FIG. 8 is a plan view schematically illustrating a pixel P of the display device 300 according to the second modification example of this embodiment.

In the display device 100 described above, as illustrated in FIG. 5, the first light-emitting region 44R has a substantially L-shape.

On the other hand, in the display device 300, as illustrated in FIG. 8, the first light-emitting region 44R has a substantially T-shape. The first light-emitting region 44R has a convex shape.

In one pixel P, in plan view, the first light-emitting region 44R has a shape including the first notch 45R on a side opposite to the second light-emitting region 44G and a fourth notch 46R on the second light-emitting region 44G side. The fourth notch 46R is provided on a side opposite to the third light-emitting region 44B. The fourth notch 46R is provided in the +X-axis direction of the first light-emitting region 44R. In the example illustrated in the drawing, the notches 45R, 45G, and 46R have a square shape.

The first pixel contact 50R (first contact hole 52R) is provided in the region of the fourth notch 46R. The first pixel contact 50R (first contact hole 52R) is not provided in the region of the first notch 45R. The third pixel contact 50B (third contact hole 52B) is provided in the region of the first notch 45R.

In the display device 300, in each of the plurality of pixels P, in plan view, the first light-emitting region 44R has a shape including the fourth notch 46R on a side opposite to the third light-emitting region 44B and on the green sub-pixel SPG side, the third pixel contact 50B (third contact hole 52B) of the blue sub-pixel SPB of the adjacent pixel P of the plurality of pixels P is provided in the region of the first notch 45R, and the first pixel contact 50R (first contact hole 52R) of the red sub-pixel SPR is provided in the region of the fourth notch 46R. For this reason, in the display device 300, it is possible to reduce the area of the region of the first notch 45R.

### 3. Electronic Apparatus

### 3.1 Overall Configuration

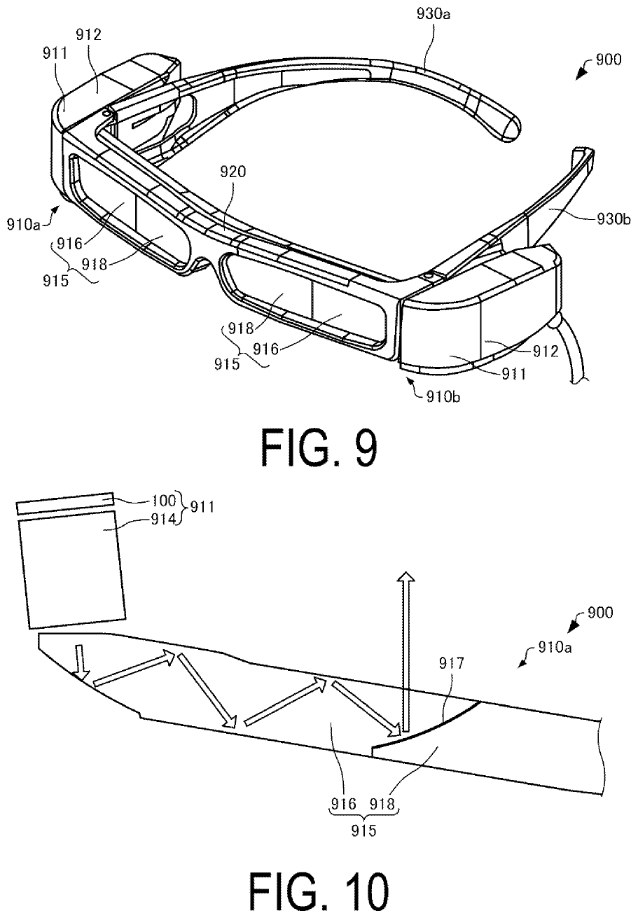

Next, a head-mounted display as an electronic apparatus according to this embodiment will be described with reference to the drawings. FIG. 9 is a perspective view schematically illustrating a head-mounted display 900 according to present embodiment.

As illustrated in FIG. 9, the head-mounted display 900 is a head-mounted display device that has a spectacle-like appearance. The head-mounted display 900 is mounted on the head of a viewer. The viewer is a user who uses the head-mounted display 900. The head-mounted display 900 allows the viewer to visually recognize image light of a virtual image and to visually recognize an external image in a see-through manner.

The head-mounted display 900 includes, for example, a first display unit 910a, a second display unit 910b, a frame 920, a first temple 930a, and a second temple 930b.

The first display unit 910a and the second display unit 910b display images. Specifically, the first display unit 910a displays a virtual image for the right eye of the viewer. The second display unit 910b displays a virtual image for the left eye of the viewer. Each of the display units 910a and 910b includes, for example, an image forming device 911 and a light-guiding device 915.

The image forming device 911 generates image light. The image forming device 911 includes, for example, an optical system such as a light source and a projection device, and an external member 912. The external member 912 accommodates the light source and the projection device.

The light-guiding device 915 covers the front of the eyes of the viewer. The light-guiding device 915 guides image light formed by the image forming device 911 and allows the viewer to visually recognize external light and the image light in an overlapping manner. Note that details of the image forming device 911 and the light-guiding device 915 will be described below.

The frame 920 supports the first display unit 910a and the second display unit 910b. For example, the frame 920 surrounds the display units 910a and 910b. In the example illustrated in the drawing, the image forming device 911 of the first display unit 910a is attached to one end portion of the frame 920. The image forming device 911 of the second display unit 910b is attached to the other end portion of the frame 920.

The first temple 930a and the second temple 930b extend from the frame 920. In the example illustrated in the drawing, the first temple 930a extends from one end portion of the frame 920. The second temple 930b extends from the other end portion of the frame 920.

The first temple 930a and the second temple 930b are put on the ears of the viewer when the head-mounted display 900 is worn on the viewer. The head of the viewer is positioned between the temples 930a and 930b.

### 3.2 Image Forming Device and Light-Guiding Device

FIG. 10 is a diagram schematically illustrating the image forming device 911 and the light-guiding device 915 of the first display unit 910a of the head-mounted display 900. Note that the first display unit 910a and the second display unit 910b have basically the same configuration. Thus, the following description on the first display unit 910a is applicable to the second display unit 910b.

As illustrated in FIG. 10, the image forming device 911 includes, for example, the display device 100 as a light source and a projection device 914 for image formation.

The projection device 914 projects the image light emitted from the display device 100 toward the light-guiding device 915. The projection device 914 is, for example, a projection lens. As the lens constituting the projection device 914, a lens including an axially symmetric surface as a lens surface may be used.

The light-guiding device 915 is accurately positioned with respect to the projection device 914 by being screwed to a lens barrel of the projection device 914, for example. The light-guiding device 915 includes, for example, an image light-guiding member 916 that guides the image light and a see-through member 918 for see-through view.

The image light emitted from the projection device 914 is incident on the image light-guiding member 916. The image light-guiding member 916 is a prism that guides the image light toward the eyes of the viewer. The image light incident on the image light-guiding member 916 is repeatedly reflected on the inner surface of the image light-guiding member 916, and then is reflected by a reflective layer 917 to be emitted from the image light-guiding member 916. The image light emitted from the image light-guiding member 916 reaches the eyes of the viewer. The reflective layer 917 is made of, for example, a metal or a dielectric multilayer film. The reflective layer 917 may be a half mirror.

The see-through member 918 is adjacent to the image light-guiding member 916. The see-through member 918 is fixed to the image light-guiding member 916. For example, the outer surface of the see-through member 918 is continuous with the outer surface of the image light-guiding member 916. The viewer sees the external light through the see-through member 918. The image light-guiding member 916 also has a function of making the viewer see through the external light therethrough, in addition to the function of guiding the image light. Note that the head-mounted display 900 may be configured not to allow the viewer to see through external light.

The electronic apparatus according to this embodiment is not limited to the head-mounted display as long as it includes the display device according to this embodiment. The electronic apparatus according to this embodiment may be an electronic view finder (EVF), a projector, a portable information terminal, a wristwatch, or an in-vehicle head-up display.

The embodiments and modification examples described above are examples and are not intended as limiting. For example, the embodiments and the modification examples can also be combined as appropriate.

The present disclosure includes configurations that are substantially identical to the configurations described in the embodiments, for example, configurations with identical functions, methods, and results, or with identical advantages and effects. In addition, the present disclosure includes configurations obtained by replacing non-essential portions of the configurations described in the embodiments. In addition, the present disclosure includes configurations having the same operational effects or configurations capable of achieving the same advantages as those of the configurations described in the embodiments. Further, the present disclosure includes configurations obtained by adding known techniques to the configurations described in the embodiments.

The following content is derived from the embodiments and modification examples described above.

A display device according to an aspect is a display device including a plurality of pixels. Each of the plurality of pixels includes: a first sub-pixel including a first light-emitting region, a first pixel electrode, and a first pixel circuit that controls light emission in the first light-emitting region, the first sub-pixel being configured to emit first color light; a second sub-pixel including a second light-emitting region, a second pixel electrode, and a second pixel circuit that controls light emission in the second light-emitting region, the second sub-pixel being configured to emit second color light different from the first color light; and a third sub-pixel including a third light-emitting region, a third pixel electrode, and a third pixel circuit that controls light emission in the third light-emitting region, the third sub-pixel being configured to emit third color light different from the first color light and the second color light. In each of the plurality of pixels, the first sub-pixel, the second sub-pixel, and the third sub-pixel are adjacent to each other; the first light-emitting region overlaps the second light-emitting region when viewed in a first direction; the third light-emitting region overlaps the first light-emitting region and the second light-emitting region when viewed in a second direction orthogonal to the first direction; the first light-emitting region has a shape including a first notch on a side opposite to the second light-emitting region in a plan view from a third direction orthogonal to the first direction and the second direction; the second light-emitting region has a shape including a second notch on a side opposite to the first light-emitting region; the first pixel electrode and the first pixel circuit are electrically coupled to each other via a first contact hole formed in an insulating layer provided between the first pixel electrode and the first pixel circuit; the second pixel electrode and the second pixel circuit are electrically coupled to each other via a second contact hole formed in an insulating layer provided between the second pixel electrode and the second pixel circuit; the third pixel electrode and the third pixel circuit are electrically coupled to each other via a third contact hole formed in an insulating layer provided between the third pixel electrode and the third pixel circuit; at least one of the first contact hole and the third contact hole of an adjacent pixel of the plurality of pixels is provided in a region of the first notch; and the second contact hole is provided in a region of the second notch.

According to the display device, color light beams emitted from the first sub-pixel, the second sub-pixel, and the third sub-pixel are easily mixed. Thereby, image quality can be improved.

In the display device according to an aspect, the first contact hole and the third contact hole of an adjacent pixel of the plurality of pixels may be provided in the region of the first notch.

According to the display device, in order to provide the third contact hole, it is not necessary to form the third light-emitting region into a shape including a notch. Thereby, the area of the third light-emitting region can be increased.

In the display device according to an aspect, in each of the plurality of pixels, the third light-emitting region may have a shape including a third notch on a side opposite to the second light-emitting region in the plan view, the first contact hole may be provided in the region of the first notch, and the third contact hole may be provided in the region of the third notch.

According to the display device, it is possible to reduce a difference between the area of the first light-emitting region, the area of the second light-emitting region, and the area of the third light-emitting region.

In the display device according to an aspect, in each of the plurality of pixels, the first light-emitting region may have a shape including a fourth notch on a side opposite to the third light-emitting region and on a side of the second sub-pixel in the plan view, the third contact hole of an adjacent pixel of the plurality of pixels may be provided in the region of the first notch, and the first contact hole may be provided in a region of the fourth notch.

According to the display device, the area of the region of the first notch can be reduced.

In the display device according to an aspect, the first light-emitting region, the second light-emitting region, and the third light-emitting region may have a shape having a longitudinal direction in the first direction, and the first light-emitting region, the second light-emitting region, and the third light-emitting region may be arranged in the first direction in the plurality of pixels.

According to the display device, it is possible to reduce a color change depending on a viewing angle.

In the display device according to an aspect, the region of the first notch may have a shape having a longitudinal direction in the first direction.

According to the display device, the width of a narrow region of the first light-emitting region can be increased.

In the display device according to an aspect, in each of the plurality of pixels, a distance between the first light-emitting region and the second light-emitting region, a distance between the second light-emitting region and the third light-emitting region, and a distance between the first light-emitting region and the third light-emitting region may be equal to each other.

According to the display device, color light beams emitted from the first light-emitting region, the second light-emitting region, and the third light-emitting region can be uniformly mixed.

An electronic apparatus according to an aspect includes the display device according to an aspect.

What is claimed is:

1. A display device comprising
a plurality of pixels, wherein
each of the plurality of pixels includes
a first sub-pixel including a first light-emitting region, a first pixel electrode, and a first pixel circuit configured to control light emission in the first light-emitting region, the first sub-pixel being configured to emit first color light,
a second sub-pixel including a second light-emitting region, a second pixel electrode, and a second pixel circuit configured to control light emission in the second light-emitting region, the second sub-pixel being configured to emit second color light different from the first color light, and
a third sub-pixel including a third light-emitting region, a third pixel electrode, and a third pixel circuit configured to control light emission in the third light-emitting region, the third sub-pixel being configured to emit third color light different from the first color light and the second color light, and
in each of the plurality of pixels,
the first sub-pixel, the second sub-pixel, and the third sub-pixel are adjacent to each other,
the first light-emitting region overlaps the second light-emitting region when viewed in a first direction,
the third light-emitting region overlaps the first light-emitting region and the second light-emitting region when viewed in a second direction orthogonal to the first direction,
the first light-emitting region has a shape including a first notch on a side opposite to the second light-emitting region in a plan view from a third direction orthogonal to the first direction and the second direction,
the second light-emitting region has a shape including a second notch on a side opposite to the first light-emitting region,
the first pixel electrode and the first pixel circuit are electrically coupled to each other via a first contact hole formed in an insulating layer provided between the first pixel electrode and the first pixel circuit,
the second pixel electrode and the second pixel circuit are electrically coupled to each other via a second contact hole formed in an insulating layer provided between the second pixel electrode and the second pixel circuit,
the third pixel electrode and the third pixel circuit are electrically coupled to each other via a third contact hole formed in an insulating layer provided between the third pixel electrode and the third pixel circuit,
at least one of the first contact hole and the third contact hole of an adjacent pixel of the plurality of pixels is provided in a region of the first notch, and
the second contact hole is provided in a region of the second notch.

2. The display device according to claim 1, wherein
the first contact hole and the third contact hole of an adjacent pixel of the plurality of pixels are provided in the region of the first notch.

3. The display device according to claim 1, wherein
in each of the plurality of pixels,
the third light-emitting region has a shape including a third notch on a side opposite to the second light-emitting region in the plan view,
the first contact hole is provided in the region of the first notch, and
the third contact hole is provided in a region of the third notch.

4. The display device according to claim 1, wherein
in each of the plurality of pixels,
the first light-emitting region has a shape including a fourth notch on a side opposite to the third light-emitting region and on a side of the second sub-pixel in the plan view,
the third contact hole of an adjacent pixel of the plurality of pixels is provided in the region of the first notch, and
the first contact hole is provided in a region of the fourth notch.

5. The display device according to claim 1, wherein
the first light-emitting region, the second light-emitting region, and the third light-emitting region have a shape having a longitudinal direction in the first direction and
the first light-emitting region, the second light-emitting region, and the third light-emitting region are arranged in the first direction in the plurality of pixels.

6. The display device according to claim 5, wherein
the region of the first notch has a shape having a longitudinal direction in the first direction in plan view.

7. The display device according to claim 1, wherein
in each of the plurality of pixels, a distance between the first light-emitting region and the second light-emitting region, a distance between the second light-emitting region and the third light-emitting region, and a distance between the first light-emitting region and the third light-emitting region are equal to each other.

8. An electronic apparatus comprising the display device according to claim 1.
